(19) United States
(12) Patent Application Publication
(10) Pub. No.: US 2025/0343172 A1
(43) Pub. Date: Nov. 6, 2025

(54) STRUCTURE WITH IC DIE WITH ENLARGED AREA IN SCRIBE REGION

(71) Applicant: GlobalFoundries Singapore Pte. Ltd., Singapore (SG)

(72) Inventors: Wanbing Yi, Singapore (SG); Ranjan Rajoo, Singapore (SG); Xiaodong Li, Singapore (SG); Weichu Qiu, Singapore (SG); Eng Chye Chua, Singapore (SG); Seok Yan Poh, Singapore (SG)

(21) Appl. No.: 18/651,838

(22) Filed: May 1, 2024

(51) Int. Cl. H01L 23/58; H01L 21/78; H01L 23/544

(52) U.S. Cl. CPC H01L 23/585; H01L 21/78; H01L 23/544; H01L 2223/5446

(57) ABSTRACT

A structure includes an IC die having an edge perimeter and an indentation extending inwardly at a portion of the edge perimeter. The structure also includes a scribe region including a first section defined along the edge perimeter of the IC die and a second section defined in the indentation. The first section has a first width relative to the edge perimeter and the second section has a second width relative to the edge perimeter greater than the first width. The second section of the scribe region provides a wider, enlarged area for wider in-frame structures, such as alignment marks, while the first section of the scribe region has a smaller width to provide area for smaller in-frame structures.

### BACKGROUND

The present disclosure relates to semiconductor structures and, more particularly, to a structure including an integrated circuit (IC) die with an enlarged area in a scribe region. A semiconductor wafer with two IC dies and a related method are also provided.

Integrated circuit (IC) dies are fabricated on a semiconductor wafer with a scribe region therebetween. The IC dies can include all varieties of integrated circuitry. The scribe region provides an area in which a cutting device, e.g., laser, can cut or dice the IC dies apart from each other and/or the semiconductor wafer. The scribe region is also used to provide in-frame structures such as inline and electrical test or monitoring structures for testing parts of the IC dies and/or alignment marks used to align fabrication-related tools to the semiconductor wafer. In one approach, scribe regions have a single and uniform width between IC dies that is sized to accommodate the widest in-frame structure used. In another approach, a first scribe region extends in one direction and has a first uniform width sized to accommodate certain in-frame structures, and a second scribe region extends perpendicular to the first scribe region and has a second, different uniform width sized to accommodate other in-frame structures. Both of these approaches result in wasted area in one or more scribe regions that cannot be used for active devices in the IC die(s).

### SUMMARY

All aspects, examples and features mentioned below can be combined in any technically possible way.

An aspect of the disclosure provides a structure, comprising: an integrated circuit (IC) die having an edge perimeter and an indentation extending inwardly at a portion of the edge perimeter; and a scribe region including a first section defined along the edge perimeter of the IC die outside the indentation and a second section defined in the indentation, the first section having a first width relative to the edge perimeter and the second section having a second width relative to the edge perimeter greater than the first width.

An aspect of the disclosure provides a semiconductor wafer, comprising: a first integrated circuit (IC) die adjacent a second IC die; each of the first IC die and the second IC die including: a die body having an edge perimeter and an indentation extending inwardly at a portion of the edge perimeter; and a scribe region including a first section defined along the edge perimeter outside the indentation and a second section defined in the indentation in each die body, the first section having a first width between the edge perimeters of the first and second IC dies and the second section having a second width between adjacent edge perimeters greater than the first width between the first and second IC dies.

An aspect of the disclosure provides a method, comprising: fabricating a first integrated circuit (IC) die adjacent a second IC die on a semiconductor wafer, the fabricating including: forming each IC die including a die body having an edge perimeter and an indentation extending inwardly at a portion of the edge perimeter, and a scribe region including a first section defined along the edge perimeter of the die body outside the indentation and a second section defined in the indentation, the first section having a first width relative to the edge perimeter and the second section having a second width relative to the edge perimeter greater than the first width; forming a first in-frame structure in the first section of the scribe region, the first in-frame structure having a third width less than the first width; and forming a second in-frame structure in the second section of the scribe region, the second in-frame structure having a fourth width less than the second width.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a schematic plan view of a pair of integrated circuit (IC) dies with a conventional scribe region therebetween;

FIG. 2 shows a plan view of a pair of IC dies with a scribe region having an enlarged area, according to embodiments of the disclosure;

FIG. 3 shows a schematic plan view of a pair of IC dies with a scribe region having an enlarged area, according to other embodiments of the disclosure;

FIG. 4 shows an enlarged plan view of sections of an enlarged area of a scribe region of an IC die in FIG. 2, according to embodiments of the disclosure;

FIG. 5 shows a plan view of a pair of IC dies with a scribe region having an enlarged area, according to other embodiments of the disclosure;

FIG. 6 shows an enlarged plan view of sections of an enlarged area of a scribe region of an IC die in FIG. 5, according to embodiments of the disclosure;

FIG. 7 shows a plan view of a structure including an IC die with a scribe region having an enlarged area, according to embodiments of the disclosure;

FIG. 8 shows a plan view of a structure including an IC die with a scribe region having an enlarged area, according to other embodiments of the disclosure;

FIG. 9 shows a plan view of a structure including an IC die with a scribe region having an enlarged area, according to yet other embodiments of the disclosure;

FIG. 10 shows a plan view of a structure including an IC die with a scribe region having an enlarged area, according to additional embodiments of the disclosure; and

FIG. 11 shows a plan view of a structure including an IC die with a scribe region having an enlarged area, according to other embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

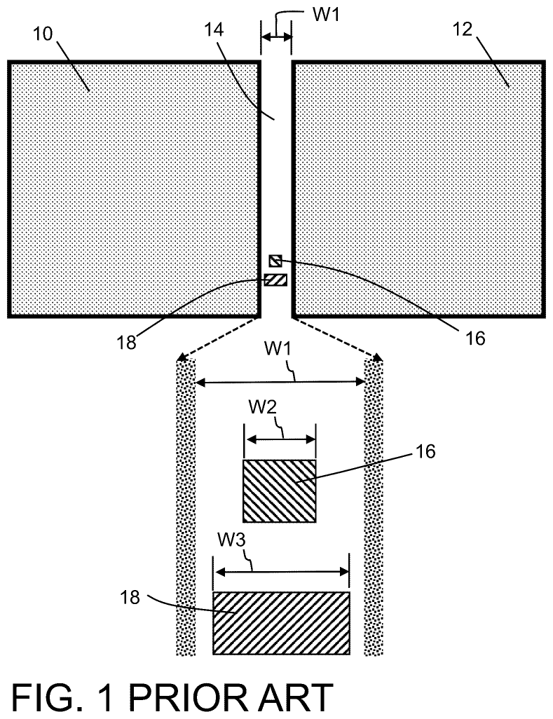

FIG. 1 shows a schematic plan view of a pair of integrated circuit (IC) dies 10, 12 according to one prior art approach to providing a scribe region 14 therebetween. Scribe region 14 includes in-frame structures such as a test structure 16 and an alignment mark 18. Scribe region 14 has a single, uniform width W1 between IC dies 10, 12. Despite test structure 16 having a width W2 that is significantly less than scribe region width W1, scribe region width W1 has to be large enough to accommodate the widest in-frame structure, which is alignment mark 18 with a width of W3. In one example, width W3 of alignment mark 18 may be 54 micrometers (μm), and scribe region width W1 may be 60 μm, i.e., 54 μm+3 μm on each side for spacing. Scribe region 14 may include a relatively large amount of space adjacent the smaller in-frame structures, e.g., test structure 16, that is unusable for IC dies 10, 12. Similar space is wasted where two perpendicular scribe regions having uniform, but different widths are used between IC dies.

Embodiments of the disclosure include a structure including an IC die having an edge perimeter and an indentation extending inwardly at a portion of the edge perimeter. The structure also includes a scribe region including a first section defined along the edge perimeter of the IC die outside the indentation and a second section defined in the indentation. The first section has a first width relative to the edge perimeter and the second section has a second width relative to the edge perimeter greater than the first width. The second section of the scribe region provides a wider, enlarged area for wider in-frame structures, such as alignment marks, while the first section of the scribe region has a smaller width to provide area for smaller in-frame structures. A semiconductor wafer may include two IC dies with indentations providing an enlarged area for larger in-frame structures. The enlarged area compared to conventional approaches provides more area for active devices in each IC die in which used, and thus effectively reduces costs. The scribe region still provides sufficient spatial margins for dicing for larger in-frame structures.

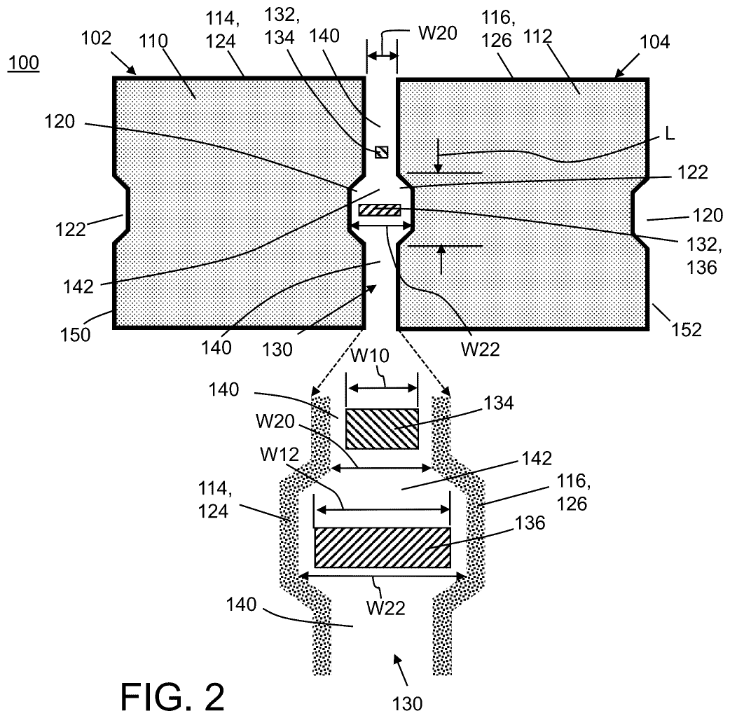

FIG. 2 shows a plan view of a portion of a semiconductor wafer 100 according to embodiments of the disclosure. Semiconductor wafer 100 (hereafter “wafer 100”) includes a first integrated circuit (IC) die 102 adjacent a second IC die 104. It will be recognized that wafer 100 may actually include hundreds or perhaps thousands of IC dies. Each IC die 102, 104 may include, among other structures, any now known or later developed integrated circuitry such as but not limited to transistors, resistors, and capacitors. IC dies 102, 104 may be fabricated using any now known or later developed semiconductor fabrication techniques. As the details of these fabrication techniques are well known in the art, except where the disclosure digresses from those techniques, no further details are required for those with skill in the art to understand the disclosure.

Each of first IC die 102 and second IC die 104 includes, respectively, a die body 110, 112 having an edge perimeter 114, 116 and an indentation 120, 122 extending inwardly at a portion of edge perimeter 114, 116. Edge perimeter 114, 116 is an edge of IC dies 102, 104 where circuitry therein no longer extends laterally in die body 110, 112. A seal ring 124, 126 extends along and defines edge perimeter 114, 116 of IC die bodies 110, 112, respectively. That is, a first seal ring 124 extends along edge perimeter 114 of die body 110 of first IC die 102 including along indentation 120 therein, and a second seal ring 126 extends along edge perimeter 116 of die body 112 of second IC die 104 including along indentation 122 therein. Note, seal rings 124, 126 are shown as a thick black line in the upper portion of FIG. 2, and as a shaded line in the enlarged, lower portion of FIG. 2.

Seal rings 124, 126 may include any now known or later developed seal ring structures within and defining edge perimeter 114, 116. For example, seal rings 124, 126 may include crack stop(s) that are within and/or surround a moisture barrier and/or a guard ring. The crack stop prevents cracking and/or unwanted stress in IC dies 102, 104 or in the moisture barrier that could lead to moisture ingress. The crack stop(s) may include any now known or later developed layered conductive elements. The guard ring and crack stop can be in any interconnect layers and can be formed using any now known or later developed semiconductor fabrication techniques. The moisture barrier may include any now known or later developed barrier configured to resist, and ideally prevent, moisture ingress, such as one or more layers of dielectric. For example, the moisture barrier may include but is not limited to one or more vertically arranged, elongated members of dielectric positioned in one or more interlayer dielectric (ILD) layers of IC dies 102, 104. In one non-limiting example, the moisture barrier may include one or more silicon nitride or other moisture impervious dielectric material layers surrounded by an ILD layer of, e.g., a low dielectric constant material. The dielectric layers may be part of any of interconnect layers of IC dies 102, 104. As the variations of arrangement of seal rings 124, 126 is well known in the art, the details thereof are not shown as no further details are required.

Wafer 100 also includes a scribe region 130 defined between IC dies 102, 104, i.e., by edge perimeter 114, 116 and seal rings 124, 126. Scribe region 130 provides an area in which a cutting device, e.g., laser, can cut or dice the IC dies 102, 104 apart from each other and/or wafer 100. As will be described, scribe region 130 also provides space for in-frame structures 132. Scribe region 130 may also be referred to as a kerf region or product frame. Scribe region 130 may include any now known or later developed dielectric material typically used between IC dies 102, 104 on a semiconductor wafer, e.g., silicon oxide. Scribe region 130 is devoid of circuitry that is part of IC dies 102, 104. Indentations 120, 122 provide room for scribe region 130, and thus, are also devoid of circuitry that is part of IC dies 102, 104. Indentations 120, 122 may also be referenced as wings or extensions of scribe region 130. IC dies 102, 104 are fabricated without circuitry in indentations 120, 122 in the same manner that scribe region 130 is formed, i.e., using any now known or later developed semiconductor fabrication techniques with modifications in patterning to include indentations 120, 122 revisions to seal ring 124, 126 and die bodies 110, 112.

Scribe region 130 may also include a variety of in-frame structures 132 typically provided between IC dies 102, 104. In-frame structures 132 may include one or more different in-frame structures 134, 136 including, but not limited to: inline and electrical test or monitoring structures for testing parts of the IC dies, electric probing pads for the test or monitoring structures, and/or alignment marks used to align fabrication-related tools to the semiconductor wafer. In-frame structures 132 may also be referred to in the art as in-kerf structures or frame structures. In the example shown, an in-frame structure 134 has a first width W10, and an in-frame structure 136 has a second width W12. In one non-limiting example, in-frame structure 134 may include an electrical pad for a test structure thereunder in scribe region 130, and in-frame structure 136 may include an alignment mark for aligning fabrication-related tools to wafer 100 and/or IC dies 102, 104. The test structures may include any form of circuitry for operative coupling to part of IC die(s) 102, 104 and allowing testing thereof, where probe pads allow selective electrical coupling to the test structures. The alignment mark may include any now known or later developed structures, e.g., metal lines arranged in a laser-identifiable layout, capable of identification by a locating device of a fabrication-related tool, e.g., an exposure stepping tool. As illustrated, width W12 of in-frame structure 136 is larger than width W10 of in-frame structure 134. In one non-limiting example, width W10 may be 35-45 micrometers (μm), and width W12 may be 50-58 μm. Typically, in-frame structures 134, 136 also have 2-3 μm on each side to space them from die bodies 110, 112 of IC dies 102, 104, respectively.

Scribe region 130 includes a first section 140 defined along edge perimeter 114, 116 outside of indentations 120, 122, and a second section 142 defined in indentation 120, 122 in each die body 110, 112. Second section 142 provides an enlarged area within an otherwise narrower scribe region 130. As illustrated, first section 140 has a width W20 between edge perimeters 114, 116 of IC dies 102, 104, and second section 142 has a width W22 between edge perimeters 114, 116 of IC dies 102, 104 greater than first width W20. Width W22 can be configured to accommodate larger in-frame structure 136 with width W12 or smaller, and width W20 can be configured to accommodate smaller in-frame structure 134 with width W10 or smaller. Based on the non-limiting example previously stated, where width W12 of larger in-frame structure 136 is 50-58 μm and 2 μm on either side is desired, width W22 of second section 142 of scribe region 130 may be 54-62 μm. In contrast to conventional approaches, where width W10 of in-frame structure 134 is 35-45 μm and 2 μm on either side is desired, width W20 of the rest of scribe region 130 (i.e., first section 140 of scribe region 130) may be, for example, 39-49 μm. Hence, first section 140 of scribe region 130 is significantly smaller than if all of scribe region 130 between two adjacent IC dies 102, 104 had been consistently and uniformly sized along its entire length for the largest width in-frame structure 136. A length L of second section 142 is configured to provide sufficient space for in-frame structure(s) 136 and minimize space used for scribe region 130. Hence, length L can be any length sufficient to allow in-frame structure(s) 136 to be formed therein. The space saved by use of second section(s) 142 can be used for circuitry in IC dies 102, 104.

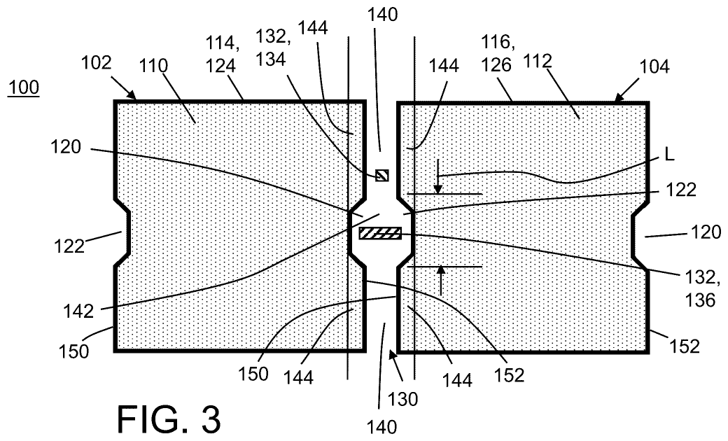

FIG. 3 shows a schematic plan view of wafer 100 with vertical line markings indicating a width of scribe region 130 were indentations 120, 122 not used for larger in-frame structures 136, i.e., with a single, consistent width sufficient to accommodate larger in-frame structures 136. As illustrated, use of indentations 120, 122 removes the need for areas 144 to be used in scribe region 130 and allows them to be used for circuitry in IC dies 102, 104.

Indentations 120, 122 can be used in any location where it is desired to save space for IC die 102, 104 by reducing wasted scribe region 130 space. In FIGS. 2 and 3, edge perimeter 114, 116 of each die body 110, 112 has a first side 150 and a second side 152 and includes an indentation 120 and 122 extending inwardly from edge perimeter 114, 116 on both first side 150 and second side 152. Indentations 120, 122 can be aligned, e.g., vertically on page, to form second section 142 of scribe region 130 between adjacent IC dies 102, 104. Scribe region 130 may also include second section 142 defined in indentations 120, 122 on both first side 150 and second side 152 of each die body 110, 112—adjacent IC dies on either side of IC dies 102, 104 omitted for clarity. Wafer 100 may also include in-frame structure(s) 136 in each second section 142 of scribe region 130, and in-frame structure(s) 134 in each first section 140 of scribe region 130. In-frame structure 136 may include but is not limited to a test structure, a pad for a test structure, and an alignment mark. While one of each sized in-frame structure 134, 136 is shown, it will be recognized that any number of in-frame structures 134, 136 may be used in each section 140, 142. Further, each in-frame structure 134, 136 may have different sized versions thereof.

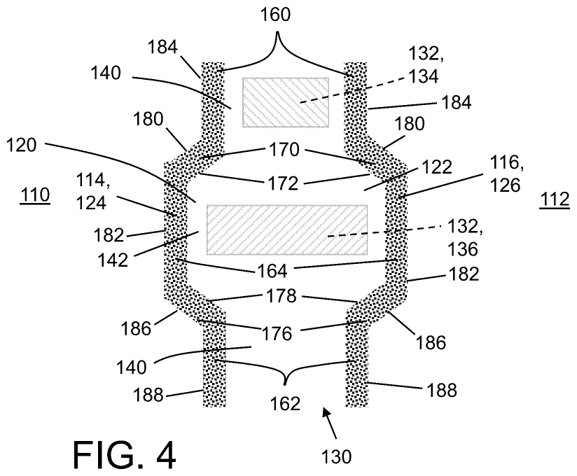

With further regard to indentations 120, 122 and first and second sections 140, 142, the indentations 120, 122 can have a variety of forms. FIG. 4 shows an enlarged plan view of an enlarged area of second section 142 in FIG. 2. As noted, first seal ring 124 extends along edge perimeter 114 of first IC die 102 (with die body 110) including along indentation 120 therein, and second seal ring 126 extends along edge perimeter 116 of second IC die 104 (with die body 112) including along indentation 122 therein. First seal ring 124 and second seal ring 126 define a shape of scribe region 130. Seal ring 124, 126 may include a first primary portion 160 along a first (upper as shown) portion of first section 140 of scribe region 130, and a second primary portion 162 along a second (lower as shown) portion of first section 140 of scribe region 130. The primary portions 160, 162 are typically straight. Seal rings 124, 126 also include an offset portion 164 offset from first and second primary portions 160, 162 and separating first primary portion 160 from second primary portion 162. If extended, offset portion 164 would be parallel to first primary portion 160 and second primary portion 162. Each offset portion 164 defines a respective indentation 120, 122 of second section 142 of scribe region 130. Seal rings 124, 126 include a first coupling portion 170 coupling an outer wall 172 (relative to die body 110, 112) of offset portion 164 to first primary portion 160 of seal ring 124, 126 at non-perpendicular angles. Seal rings 124, 126 also include a second coupling portion 176 coupling an outer wall 178 (relative to die body 110, 112) of offset portion 164 to second primary portion 162 of seal ring 124, 126 at non-perpendicular angles.

Coupling portions 170, 176 may have different forms of inner walls, i.e., walls facing into die body 110, 112. In FIG. 4, for each seal ring 124, 126, first coupling portion 170 includes a linear inner wall 180 coupling an inner wall 182 of offset portion 164 to an inner wall 184 of first primary portion 160 of seal ring 124, 126 at non-perpendicular angles. Further, for each seal ring 124, 126, second coupling portion 176 includes a linear inner wall 186 coupling inner wall 182 of offset portion 164 to an inner wall 188 of second primary portion 162 of seal ring 124, 126 at non-perpendicular angles. Hence, inner walls 180 of coupling portions 170 are angled at non-perpendicular angles relative to inner walls 184 of first primary portion 160, and inner walls 186 of coupling portions 176 are angled at non-perpendicular angles relative to inner walls 188 of second primary portion 162.

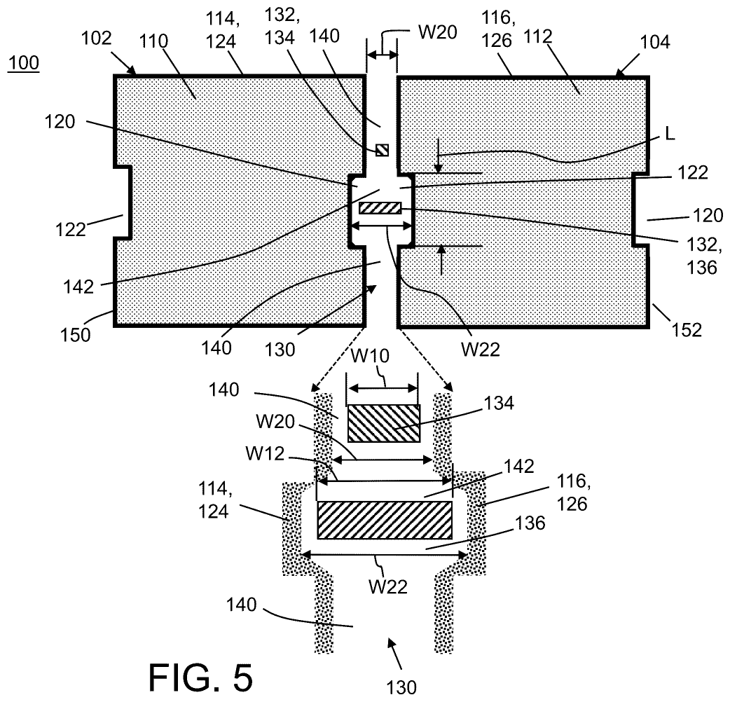

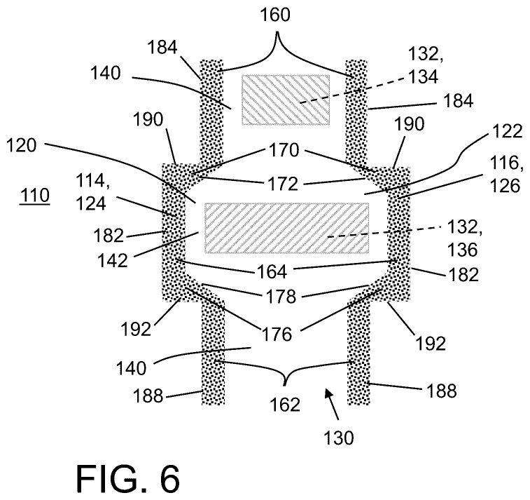

FIG. 5 shows a plan view of a portion of wafer 100 according to other embodiments of the disclosure, and FIG. 6 shows an enlarged plan view of an enlarged area of second section 142 in FIG. 5. FIGS. 5 and 6 are similar to FIGS. 2 and 4, except indentations 120, 122 have more squared off inner shapes. More particularly, as shown in FIG. 6, first coupling portion 170 includes a right-angle inner wall 190 coupling inner wall 182 of offset portion 164 to inner wall 184 of first primary portion 160 of seal ring 124, 126 at a perpendicular angle. Similarly, second coupling portion 176 includes a right-angle inner wall 192 coupling inner wall 182 of offset portion 164 to inner wall 188 of second primary portion 162 of seal ring 124, 126 at a perpendicular angle. The variations in inner wall shapes of coupling portions 170, 176 can be configured to address any variety of purposes, such as reducing stress in seal rings 124, 126 and preventing cracking, delamination, etc.

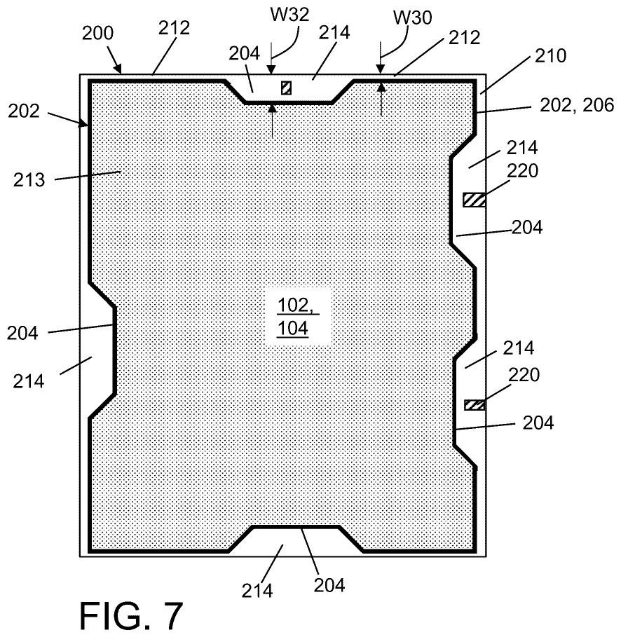

As noted, indentations 120, 122 in edge perimeter 114, 116 and wider second sections 142 of scribe regions 130 may be used in any location on an IC die 102, 104 to provide space for larger in-frame structures 132 and less wasted area for die bodies 110, 112 of IC dies 102, 104. FIGS. 7-11 show plan views of a structure 200 including IC die 102 or 104 according to various embodiments of the disclosure. More particularly, FIGS. 7-11 show structures 200 including IC die 102 or 104 after dicing from wafer 100 (as shown, e.g., in FIGS. 2 and 5). Any of the structures 200 shown in FIGS. 7-11 can be used in wafer 100, as described herein, to accommodate any variety of differently sized in-frame structures 132.

In FIGS. 7-11, each structure 200 includes an IC die (102 or 104) having edge perimeter 202 and indentation 204 extending inwardly at a portion of edge perimeter 202 (defined by seal ring 206). Structure 200 also includes a scribe region 210 including a first section 212 defined along edge perimeter 202 of IC die 102, 104, i.e., die body 213 thereof, and a second section 214 defined in indentation 204. As shown in FIG. 7, first section 212 has a width W30 relative to edge perimeter 202 and second section 214 has a width W32 relative to edge perimeter 202 greater than width W30. Here, after dicing and with the IC die separated from the rest of wafer 100, the widths are measured relative to edge perimeter 202 rather than between edge perimeters of adjacent IC dies 102, 104 as in, for example, FIGS. 2 and 5. After dicing and depending on the size of in-frame structure 136 (FIGS. 2-6) in second section 214 (note, second section is 142 in wafer 100 in FIGS. 2-6), structure 200 may also include one or more remnants 220 of in-frame structure 136 (FIGS. 2 and 5) in second section 214 of scribe region 210. Remnant(s) 220 of in-frame structure 136 (FIGS. 2-6) remain in second section 214 of scribe region 210 if it is wide enough to not be removed by the dicing tool. This may be the case, for example, where in-frame structure(s) 136 (FIGS. 2-6) extend inwardly of edge perimeter 202 in second section 214 of scribe region 210. Remnant(s) 220 of in-frame structure 136 (FIGS. 2-6) may be any part of the types of possible in-frame structures 132 (FIGS. 2-6) described herein, e.g., a test structure, a pad for a test structure, and an alignment mark.

Structure 200 also includes seal ring 206 extending along edge perimeter 202 of IC die 102, 104 including along indentation 204. Seal ring 206 defines a shape of scribe region 210 as previously described herein relative to FIGS. 4 and 6.

FIG. 7 shows an option in which structure 200 and, in particular, IC die 102, 104 has four sides and each side includes at least one indentation 204 extending inwardly at a portion of an edge perimeter 202 (defined by seal ring 206) thereof. Here, a scribe region 210 includes first section 212 defined along edge perimeter 202 of IC die 102 or 104 of structure 200 on each side and second section 214 defined in indentation 204 on each side. For each side, first section 212 thereon has a width W30 relative to edge perimeter 202 less than a width W32 relative to edge perimeter 202 of second section 214 thereon. The right side in FIG. 7 includes two indentations 204 and second sections 214 of scribe region 210. Some of the second sections 214 in FIG. 7 include a remnant 220 of an in-frame structure 136 (FIGS. 2-6).

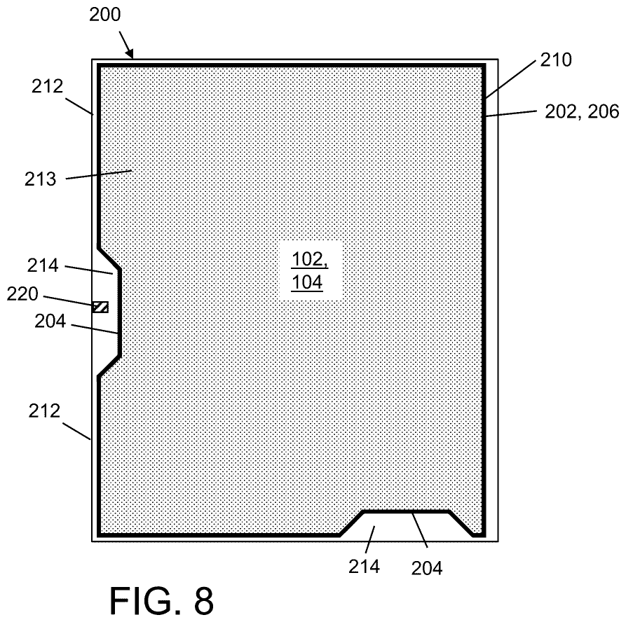

FIG. 8 shows a structure 200 in which IC die 102 or 104 have two indentations 204 and second sections 214 of scribe region 210 on adjacent but not opposing sides. One or more remnants 220 are in a second section 214 of scribe region 210 on one side (left side) of IC die 102, 104, but are not in a second section 214 of scribe region 210 in the other side (bottom side).

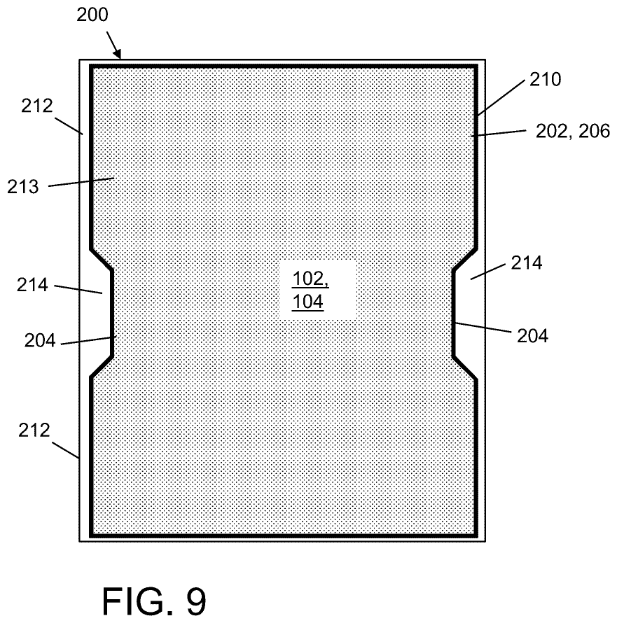

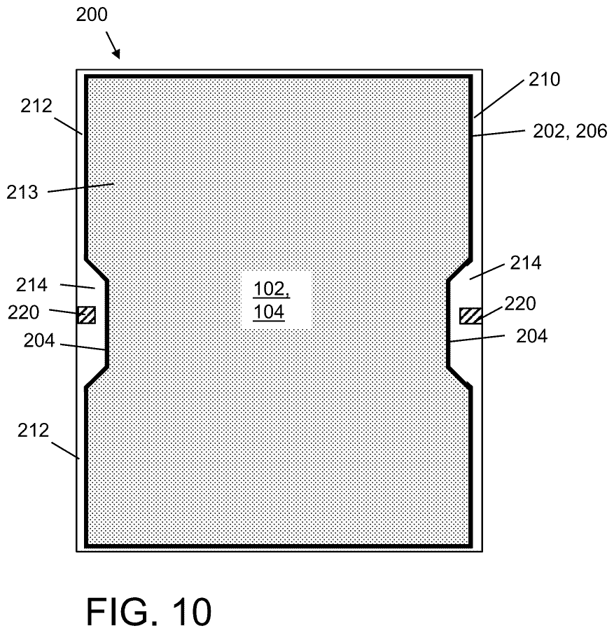

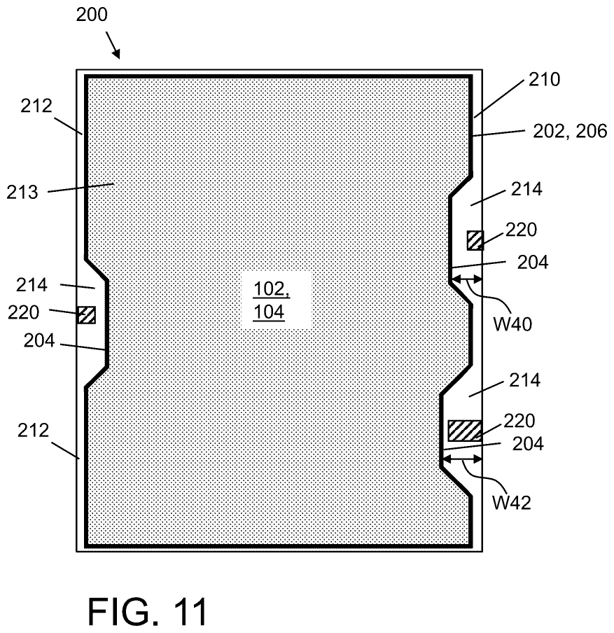

FIG. 9 shows a structure 200 in which IC structure 200 has the configuration as shown in FIG. 2, but with no remnants in second sections 214. FIG. 10 shows a structure 200 similar to FIG. 9, but with remnants 220 in each second section 214 of scribe region 210. While one second section 142 having a particular width is shown in most cases in FIGS. 2-10, it will be recognized that more than one second section 142, i.e., more than one enlarged area, with different widths can be used in a given IC die body 110, 112, and even within a given side of an IC die body 110, 112. FIG. 11 shows a structure 200 similar to FIGS. 9 and 10, but with different width second sections 214 on the right side thereof (they could be in any side). Compare widths W40 and W42. FIG. 11 also includes different sized remnants 220 in each second section 214 of scribe region 210. Typically, as shown in FIGS. 2 and 4, second sections 142 of scribe region 130 (and indentations 120, 122) on adjacent IC dies 102, 104 are the same width, but this is not necessary in all cases.

As noted, any of the structures 200 shown in FIG. 2-11 can be used in wafer 100, as described herein, to accommodate any variety of differently sized in-frame structures 132, i.e., the different versions can be mixed and matched as necessary to address different sized in-frame structures 132.

Returning to FIGS. 2 and 5, a method according to embodiments of the disclosure may include fabricating first IC die 102 adjacent second IC die 104 on wafer 100. The fabricating may include forming each IC die 102, 104 including die body 110, 112 having edge perimeter 114, 116 and indentation 120, 122 extending inwardly at a portion of edge perimeter 114, 116. The fabricating may also include forming scribe region 130 including first section 140 defined along edge perimeter 114, 116 of die body 110, 112 outside indentation 120, 122 and second section 142 defined in indentation 120, 122. As described herein, and shown in FIGS. 2 and 5, first section 140 has width W20 between edge perimeters 114, 116 and second section 142 has width W22 between edge perimeters 114, 116 greater than width W20.

The fabricating may also include forming first in-frame structure 134 in first section 140 of scribe region 130 having width W10 less than width W20 and forming second in-frame structure 136 in second section 142 of scribe region 130. Second in-frame structure 136 has width W12 less than width W22. The fabricating may also include forming seal ring 124, 126 along edge perimeter 114, 116 and along indentation 120, 122. The fabricating described may include any now known or later developed semiconductor fabrication techniques with modifications in patterning to include indentations 120, 122 in seal ring 124, 126. The method may also include dicing wafer 100, resulting in structures 200 as described relative to FIGS. 7-11.

Embodiments of the disclosure provide various technical and commercial advantages, examples of which are discussed herein. The structure provides an IC die with the second section of the scribe region providing a wider, enlarged area for wider in-frame structures, such as alignment marks, while the first section of the scribe region has a smaller width to provide area for smaller in-frame structures. A semiconductor wafer may include two IC dies with indentations providing an enlarged area for larger in-frame structures. The enlarged area compared to conventional approaches provides more area for active devices in IC die(s) in which used, and thus effectively reduces costs. However, the scribe region still provides sufficient spatial margins for dicing for larger in-frame structures.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
an integrated circuit (IC) die having an edge perimeter and an indentation extending inwardly at a portion of the edge perimeter; and
a scribe region including a first section defined along the edge perimeter of the IC die outside the indentation and a second section defined in the indentation, the first section having a first width relative to the edge perimeter and the second section having a second width relative to the edge perimeter greater than the first width.

2. The structure of claim 1, further comprising a remnant of an in-frame structure in the second section of the scribe region.

3. The structure of claim 2, wherein the remnant of the in-frame structure is selected from a group comprising a portion of: a test structure, a pad for a test structure, and an alignment mark.

4. The structure of claim 1, wherein the IC die has a first side and a second side and includes an indentation extending inwardly from the edge perimeter on both the first side and the second side, and
wherein the scribe region includes the second section defined in the indentation on both the first side and the second side, and
further comprising a remnant of an in-frame structure in each second section of the scribe region.

5. The structure of claim 1, further comprising a seal ring extending along the edge perimeter of the IC die including along the indentation.

6. The structure of claim 5, wherein the seal ring defines a shape of the scribe region and includes:
a first primary portion along a first portion of the first section of the scribe region;
a second primary portion along a second portion of the first section of the scribe region;
an offset portion offset from the first and second primary portions and separating the first primary portion from the second primary portion, the offset portion defining the indentation in the portion of the edge perimeter;
a first coupling portion coupling an outer wall of the offset portion to the first primary portion of the seal ring at non-perpendicular angles; and
a second coupling portion coupling an outer wall of the offset portion to the second primary portion of the seal ring at non-perpendicular angles.

7. The structure of claim 6, wherein the first coupling portion includes a linear inner wall coupling an inner wall of the offset portion to an inner wall of the first primary portion of the seal ring at non-perpendicular angles, and the second coupling portion includes a linear inner wall coupling an inner wall of the offset portion to an inner wall of the second primary portion of the seal ring at non-perpendicular angles.

8. The structure of claim 6, wherein the first coupling portion includes a right-angle inner wall coupling an inner wall of the offset portion to an inner wall of the first primary portion of the seal ring at a perpendicular angle, and the second coupling portion includes a right-angle inner wall coupling an inner wall of the offset portion to an inner wall of the second primary portion of the seal ring at a perpendicular angle.

9. The structure of claim 1, wherein the IC die has four sides and each side includes the indentation extending inwardly at a portion of the edge perimeter, and
wherein the scribe region includes the first section defined along the edge perimeter of the IC die on each side and the second section defined in the indentation on each side,
wherein, for each side, the first section thereon has a width relative to the edge perimeter less than a width relative to the edge perimeter of the second section thereon.

10. A semiconductor wafer, comprising:
a first integrated circuit (IC) die adjacent a second IC die;
each of the first IC die and the second IC die including:
a die body having an edge perimeter and an indentation extending inwardly at a portion of the edge perimeter; and
a scribe region including a first section defined along the edge perimeter outside the indentation and a second section defined in the indentation in each die body, the first section having a first width between the edge perimeters of the first and second IC dies and the second section having a second width between adjacent edge perimeters greater than the first width between the first and second IC dies.

11. The semiconductor wafer of claim 10, further comprising an in-frame structure in each second section of the scribe region.

12. The semiconductor wafer of claim 11, wherein the in-frame structure is selected from a group comprising: a test structure, a pad for a test structure, and an alignment mark.

13. The semiconductor wafer of claim 10, wherein the edge perimeter of each die body has a first side and a second side and includes an indentation extending inwardly from the edge perimeter on both the first side and the second side, and
wherein the scribe region includes the second section defined in the indentation on both the first side and the second side of each die body, and
further comprising an in-frame structure in each second section of the scribe region.

14. The semiconductor wafer of claim 10, further comprising a first seal ring extending along the edge perimeter of the first IC die including along the indentation therein, and a second seal ring extending along the edge perimeter of the second IC die including along the indentation therein.

15. The semiconductor wafer of claim 14, wherein the first seal ring and the second seal ring define a shape of the scribe region and each include:
a first primary portion along a first portion of the first section of the scribe region;
a second primary portion along a second portion of the first section of the scribe region;
an offset portion offset from the first and second primary portions and separating the first primary portion from the second primary portion, the offset portion defining the indentation in the portion of the edge perimeter;
a first coupling portion coupling an outer wall of the offset portion to the first primary portion of the seal ring at non-perpendicular angles; and
a second coupling portion coupling an outer wall of the offset portion to the second primary portion of the seal ring at non-perpendicular angles.

16. The semiconductor wafer of claim 15, wherein, for each seal ring, the first coupling portion includes a linear inner wall coupling an inner wall of the offset portion to an inner wall of the first primary portion of the seal ring at non-perpendicular angles, and the second coupling portion includes a linear inner wall coupling an inner wall of the offset portion to an inner wall of the second primary portion of the seal ring at non-perpendicular angles.

17. The semiconductor wafer of claim 15, wherein, for each seal ring, the first coupling portion includes a right-angle inner wall coupling an inner wall of the offset portion to an inner wall of the first primary portion of the seal ring at a perpendicular angle, and the second coupling portion includes a right-angle inner wall coupling an inner wall of the offset portion to an inner wall of the second primary portion of the seal ring at a perpendicular angle.

18. The semiconductor wafer of claim 10, wherein the IC die has four sides and each side includes the indentation extending inwardly at a portion of the edge perimeter, and
wherein the scribe region includes the first section defined along the edge perimeter of the IC die on each side and the second section defined in the indentation on each side,
wherein, for each side, the first section thereon has a width relative to the edge perimeter less than a width relative to the edge perimeter of the second section thereon.

19. A method, comprising:
fabricating a first integrated circuit (IC) die adjacent a second IC die on a semiconductor wafer, the fabricating including:
forming each IC die having a die body having an edge perimeter and an indentation extending inwardly at a portion of the edge perimeter, and a scribe region including a first section defined along the edge perimeter of the die body outside the indentation and a second section defined in the indentation, the first section having a first width relative to the edge perimeter and the second section having a second width relative to the edge perimeter greater than the first width;
forming a first in-frame structure in the first section of the scribe region, the first in-frame structure having a third width less than the first width; and
forming a second in-frame structure in the second section of the scribe region, the second in-frame structure having a fourth width less than the second width.

20. The method of claim 19, wherein forming each IC die includes forming a seal ring along the edge perimeter and along the indentation.
